(19) United States
(12) Patent Application Publication
(10) Pub. No.: US 2026/0072070 A1
(43) Pub. Date: Mar. 12, 2026

(54) ENHANCED DETECTION OF INSTABILITY REGIONS IN POWER SYSTEMS WITH INVERTER-BASED RESOURCES

(71) Applicant: GE Infrastructure Technology LLC, Greenville, SC (US)

(72) Inventors: Hanchao LIU, Niskayuna, NY (US); Dongsen SUN, Philadelphia, PA (US); Maozhong GONG, Niskayuna, NY (US); Zhe CHEN, Niskayuna, NY (US); Philip Joseph HART, Niskayuna, NY (US)

(73) Assignee: GE Infrastructure Technology LLC, Greenville, SC (US)

(21) Appl. No.: 18/830,015

(22) Filed: Sep. 10, 2024

(51) Int. Cl. G01R 31/08; G01R 27/16

(52) U.S. Cl. CPC G01R 31/088; G01R 27/16; G01R 31/086

(57) ABSTRACT

Methods, systems, and devices for detecting instabilities and their root causes in power networks may include identifying a network impedance matrix of a power network; determining impedance matrices for inverter-based resources (IBRs) of the power network; generating, by the at least one processor, a characteristic impedance matrix based on a product of the network impedance matrix and an IBR impedance matrix of the impedance matrices; determining a first sensitivity matrix of an n^{th} eigenvalue of the characteristic impedance matrix on the network impedance matrix; determining a second sensitivity matrix of the n^{th} eigenvalue of the characteristic impedance matrix on the IBR impedance matrix; identifying a first peak of the first sensitivity matrix and a second peak of the second sensitivity matrix; and determining, based on the first peak and the second peak, that at least one bus of the power network is a root cause of an instability.

### STATEMENT REGARDING FEDERALLY SPONSORED RESEARCH OR DEVELOPMENT

This invention was made with Government support under Contract No. DE-EE0009024 awarded by the United States Department of Energy. The Government has certain rights in this invention.

### TECHNICAL FIELD

This disclosure generally relates to power systems, and more specifically to detection of instabilities in power systems with inverter-based resources.

### BACKGROUND

The penetration level of inverter-based resources (IBRs) are increasing in power grid. The increasing numbers of IBRs create reliability challenges, including 1) unexpected tripping of large amounts of IBRs during grid events, as shown in North American Electric Reliability Corporation (NERC) disturbance event reports; 2) rise of control interactions and oscillation events; 3) declining system inertia and frequency stability due to the displacement of synchronous generators; and 4) declining grid strength and voltage stability. It is critical for system operators to have situational awareness of root causes of grid instability.

### SUMMARY

A method for detecting power network instability and root cause may include identifying, by at least one processor, a network impedance matrix of a power network; determining, by the at least one processor, impedance matrices for inverter-based resources (IBRs) of the power network; generating, by the at least one processor, a characteristic impedance matrix based on a product of the network impedance matrix and an IBR impedance matrix of the impedance matrices; determining, by the at least one processor, a first sensitivity matrix of an n^{th} eigenvalue of the characteristic impedance matrix on the network impedance matrix; determining, by the at least one processor, a second sensitivity matrix of the n^{th} eigenvalue of the characteristic impedance matrix on the IBR impedance matrix; identifying, by the at least one processor, a first peak of the first sensitivity matrix; identifying, by the at least one processor, a second peak of the second sensitivity matrix; determining, by the at least one processor, based on the first peak, that a first bus of the power network is a root cause of an instability in the power network; and determining, by the at least one processor, based on the second peak, that the first bus or a second bus of the power network is associated with the root cause of the instability in the power network.

A system for detecting power network instability and root cause may include a power network; and memory coupled to at least one processor configured to: identify a network impedance matrix of the power network; determine impedance matrices for inverter-based resources (IBRs) of the power network; generate a characteristic impedance matrix based on a product of the network impedance matrix and an IBR impedance matrix of the impedance matrices; determine a first sensitivity matrix of an n^{th} eigenvalue of the characteristic impedance matrix on the network impedance matrix; determine a second sensitivity matrix of the n^{th} eigenvalue of the characteristic impedance matrix on the IBR impedance matrix; identify a first peak of the first sensitivity matrix; identify a second peak of the second sensitivity matrix; determine, based on the first peak, that a first bus of the power network is a root cause of an instability in the power network; and determine, based on the second peak, that the first bus or a second bus of the power network is associated with the root cause of the instability in the power network.

A non-transitory computer-readable medium storing instructions for detecting power network instability and root cause that, when executed by one or more processors, causes the one more processors to: identify a network impedance matrix of the power network; determine impedance matrices for inverter-based resources (IBRs) of the power network; generate a characteristic impedance matrix based on a product of the network impedance matrix and an IBR impedance matrix of the impedance matrices; determine a first sensitivity matrix of an n^{th} eigenvalue of the characteristic impedance matrix on the network impedance matrix; determine a second sensitivity matrix of the n^{th} eigenvalue of the characteristic impedance matrix on the IBR impedance matrix; identify a first peak of the first sensitivity matrix; identify a second peak of the second sensitivity matrix; determine, based on the first peak, that a first bus of the power network is a root cause of an instability in the power network; and determine, based on the second peak, that the first bus or a second bus of the power network is associated with the root cause of the instability in the power network.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 shows an example process 100 for inverter-based resource (IBR) system stability analysis and unstable region identification in accordance with one embodiment of the present disclosure.

FIG. 2 is an example process 200 for generating the network impedance matrix in accordance with one embodiment of the present disclosure.

FIG. 3 is a Nyquist plot of an eigenvalue of the characteristic matrix in accordance with one embodiment of the present disclosure.

FIG. 4 is a plot of the sensitivity matrix of the n^{th} eigenvalue of a characteristic matrix on IBR impedance in accordance with one embodiment of the present disclosure.

FIG. 5 is a plot of the sensitivity matrix of the n^{th} eigenvalue of a characteristic matrix on network impedance in accordance with one embodiment of the present disclosure.

FIG. 6 is a diagram illustrating an example of a computing system that may be used in implementing embodiments of the present disclosure.

Certain implementations will now be described more fully below with reference to the accompanying drawings, in which various implementations and/or aspects are shown. However, various aspects may be implemented in many different forms and should not be construed as limited to the implementations set forth herein; rather, these implementations are provided so that this disclosure will be thorough and complete, and will fully convey the scope of the disclosure to those skilled in the art. Like numbers in the figures refer to like elements throughout. Hence, if a feature is used across several drawings, the number used to identify the feature in the drawing where the feature first appeared will be used in later drawings.

### DETAILED DESCRIPTION

Bulk power systems are increasingly integrating renewable energy sources. The integration of these energy sources occurs through power electronics, such as inverters, which have faster control dynamics. An inverter is a power electronic device that converts direct current to alternating current. Inverter-based resources (IBRs) include wind turbines, solar photovoltaic, battery storage, high-voltage direct current circuits, static synchronous compensators, and the like, which connect to the grid using inverters and/or converters (e.g., alternating current/direct current converters). IBRs usually include an energy source, an inverter, a step-up transformer, a collector system, a substation, and controller, and a point of interconnection.

With an increasing interconnection of IBRs in power systems, there is an increasing potential of power system control interactions between IBRs and grids. There is a need for an improved ability to predict instabilities in power systems with IBRs, the locations of the instabilities, and the root causes of the instabilities, to improve power system stability.

In one or more embodiments, enhanced power system instability detection may use impedance-based techniques for large-scale power system stability analysis. Impedance is a terminal characteristic of a large power system. Comparing a power network impedance (e.g., network impedance matrix, denoted as a Z-matrix) with individual IBR impedance may provide a strong indicator of power network instability. The analysis may be performed offline (e.g., planning stage) or in the online (e.g., operation) stage. Once the instability is predicted, the enhanced techniques herein allow for detecting the location of the predicted instability, which current techniques do not perform.

As a result of the enhanced techniques herein, the analyses of power networks will improve accuracy of detecting instabilities in power networks and in diagnosing the root causes of those power network instabilities.

An impedance matrix indicates the behavior of the power network. For N ports of the power network, the impedance matrix Z is a N×N matrix whose elements are complex numbers and frequency functions. The stability margin of the power network may use the Nyquist stability technique (e.g., the Nyquist plot of frequency response). For example, the Nyquist plot for

$$G ( s ) = \frac{1}{{s}^{2} + s + 1} ,$$

with the real part of the transfer function on the X-axis and the imaginary part on the Y-axis, with one point per frequency. The stability is calculated by identifying the number of encirclements of the coordinate (−1+j0).

In one or more embodiments, the enhanced automated process may obtain the network impedance matrix, which is predefined information for a power network. Then, the process may derive impedance models of the IBRs of the power network, obtained. from analytical models, numerical simulation or hardware measurements. The process may combine the network impedance matrix and the IBR impedance models and may perform an impedance-based stability analysis to predict the stability. The process may construct an equivalent multiple input multiple output (MIMO) feedback system with which to identify the root cause of the instability. By using a partial derivative of the characteristic matrix, the process may detect from where in the power network the instability is (e.g., which portion of the network is contributing most to the instability).

The network impedance matrix may include both bus information and line information from the network. To generate the network impedance matrix, power system network information is imported. The bus may be sorted with a particular order, and the diagonal and off-diagonal element may be calculated. A Kron reduction may eliminate elements in the diagonal and off-diagonal element without a source connection. Then, the network impedance matrix may be resorted per the characteristics of the IBRs to obtain the network impedance matrix. The IBR impedance matrix may be formed by the impedance of the IBRs, and may be obtained from measurements, analytical models, or numerical approximation. For example, the IBR sequence impedances may be from analytical models or measurements, such as an automatic tool for electromagnetic transient (EMT) model impedance sweeping, like PSCAD (Power Systems Computer Aided Design) and RTDS, for example.

The characteristic matrix L=G_{cd}G_{nw}, where G_{cd} is the automatic generation impedance matrix for an IBR, and G_{nw} is the power network impedance matrix (e.g., combining the network impedance matrix and the IBR impedance matrix). Predicting the stability includes determining the eigenvalues of the characteristic matrix. The system is stable if and only if the Nyquist plots of all eigenvalues of the characteristic matrix L does not encircle the critical point (−1+j0).

When the system is unstable (e.g., as indicated by the Nyquist plots of the eigenvalues of the characteristic matrix), the enhanced techniques herein may determine the location that is the root cause of the instability by evaluating the sensitivity of the eigenvalue on both the network impedance matrix and the IBR impedance matrix. The sensitivity matrix of the n^{th} eigenvalue of characteristic matrix L on G_{cd} is:

$${T}_{c d} = \frac{\partial L}{\partial {G}_{c {d}_{ij}}} = {u}_{n}^{T} \frac{\partial {G}_{c d}}{\partial {G}_{c {d}_{ij}}} {G}_{n w} {w}_{n} + {u}_{n}^{T} {G}_{c d} \frac{\partial {G}_{n w}}{\partial {G}_{c {d}_{ij}}} {w}_{n} ,$$

where uₙ and wₙ are the n^{th} left and right eigenvector of L, respectively. The sensitivity matrix of the n^{th} eigenvalue of characteristic matrix L on G_{nw} is:

$${T}_{n w} = \frac{\partial L}{\partial {G}_{n {w}_{ij}}} = {u}_{n}^{T} \frac{\partial {G}_{c d}}{\partial {G}_{n {w}_{ij}}} {G}_{n w} {w}_{n} + {u}_{n}^{T} {G}_{c d} \frac{\partial {G}_{n w}}{\partial {G}_{n {w}_{ij}}} {w}_{n} , and$$

$$\frac{\partial {G}_{n w}}{\partial {G}_{c {d}_{ij}}} = \frac{\partial {G}_{c d}}{\partial {G}_{n {w}_{ij}}} = 0 .$$

In one or more embodiments, examining T_{cd} and T_{nw}, the peaks may be identified. Either the highest respective peak of T_{cd} and T_{nw} is selected, or any peaks above a threshold sensitivity may be selected. The peaks correspond to a particular bus in the system, so the bus with the highest peak (or any bus with a peak exceeding a threshold) may be considered the root cause of the instability.

The above descriptions are for purposes of illustration and are not meant to be limiting. Numerous other examples, configurations, processes, etc., may exist, some of which are described in greater detail below. Example embodiments will now be described with reference to the accompanying figures.

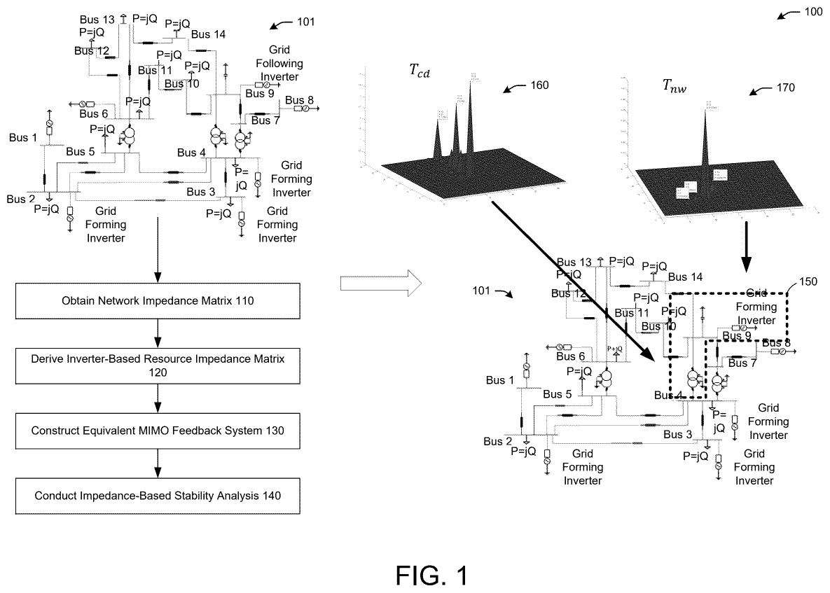

FIG. 1 shows an example process 100 for IBR system stability analysis and unstable region identification in accordance with one embodiment of the present disclosure.

Referring to FIG. 1, a power network 101 is shown, having buses 1-14 and multiple grid following or grid forming inverters (e.g., IBRs). The process 100 may obtain the network impedance matrix 110 for the power network 101. The process 100 may include deriving an impedance matrix 120 of the IBRs of the power network 101. The process 100 may include constructing an equivalent MIMO feedback system 130 for the power network 101. The process 100 may include conducting an impedance-based stability analysis 140 for the power network 101. As a result, the process 100 may perform a sensitivity analysis to identify an unstable region 150 of the power network 101.

The unstable region 150 may be identified using plot 150 of the sensitivity of the IBR impedance matrix and plot 160 of the sensitivity of the network impedance matrix. Peaks exceeding threshold values in the plots may indicate where the root causes of the sensitivity region 150 are. In the example of FIG. 1, the plot 150 shows a highest peak on Bus 9, and the plot 160 shows a highest peak on Bus 4, corresponding to the sensitivity region 150. For example, the sensitivity analysis may indicate that the resonances may be the interaction between Bus 9 and Bus 4, so reducing the leakage inductance of the transformer between Bus 4 and Bus 9 may stabilize the power network 101.

The characteristic matrix L=G_{cd}G_{nw}, where G_{cd} is the automatic generation impedance matrix for an IBR, and G_{nw} is the power network impedance matrix (e.g., combining the network impedance matrix and the IBR impedance matrix). Predicting the stability includes determining the eigenvalues of the characteristic matrix. The power network 101 is stable if and only if the Nyquist plots of all eigenvalues of the characteristic matrix L does not encircle the critical point (−1+j0).

When the power network 101 is unstable (e.g., as indicated by the Nyquist plots of the eigenvalues of the characteristic matrix), the enhanced techniques herein may determine the location that is the root cause of the instability by evaluating the sensitivity of the eigenvalue on both the network impedance matrix and the IBR impedance matrix. The sensitivity matrix of the n^{th} eigenvalue of characteristic matrix L on G_{cd} is:

$${T}_{c d} = \frac{\partial L}{\partial {G}_{c {d}_{ij}}} = {u}_{n}^{T} \frac{\partial {G}_{c d}}{\partial {G}_{c {d}_{ij}}} {G}_{n w} {w}_{n} + {u}_{n}^{T} {G}_{c d} \frac{\partial {G}_{n w}}{\partial {G}_{c {d}_{ij}}} {w}_{n} ,$$

where uₙ and wₙ are the n^{th} left and right

eigenvector of L, respectively. The sensitivity matrix of the n^{th} eigenvalue of characteristic matrix L on G_{nw} is:

$${T}_{n w} = \frac{\partial L}{\partial {G}_{n {w}_{ij}}} = {u}_{n}^{T} \frac{\partial {G}_{c d}}{\partial {G}_{n {w}_{ij}}} {G}_{n w} {w}_{n} + {u}_{n}^{T} {G}_{c d} \frac{\partial {G}_{n w}}{\partial {G}_{n {w}_{ij}}} {w}_{n} , and$$

$$\frac{\partial {G}_{n w}}{\partial {G}_{c {d}_{ij}}} = \frac{\partial {G}_{c d}}{\partial {G}_{n {w}_{ij}}} = 0 .$$

In one or more embodiments, examining T_{cd} and T_{nw}, highest value may be identified as the peaks as in plots 150 and 160. Either the highest respective peak of T_{cd} and T_{nw} is selected, or any peaks above a threshold sensitivity may be selected. The peaks correspond to a particular bus in the system, so the bus with the highest peak (or any bus with a peak exceeding a threshold) may be considered the root cause of the instability.

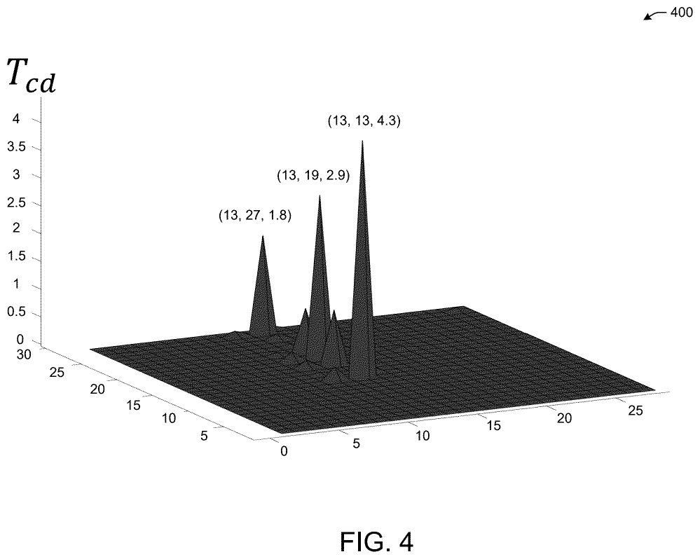

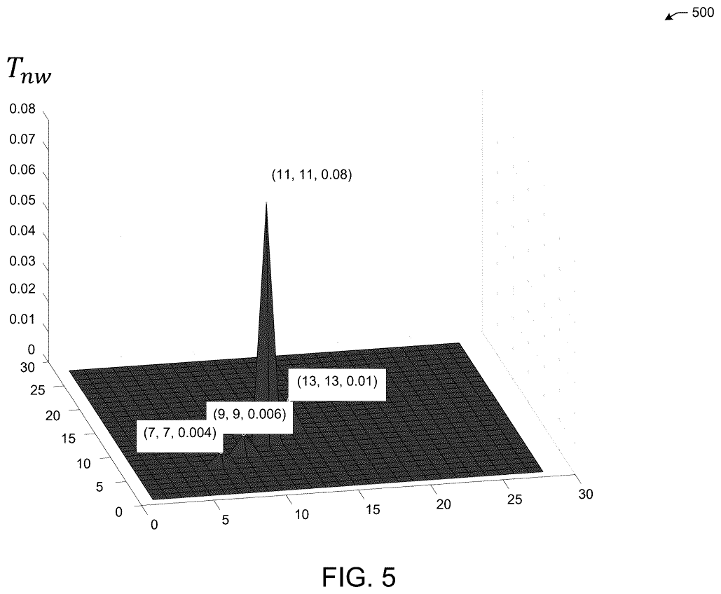

In one or more embodiments, as shown in FIGS. 4 and 5, the X and Y-axes of the plots 150 and 160 correspond to the respective matrix values (e.g., the rows and columns may correspond to the buses), and the Z-axis corresponds to the sensitivity value of the buses in the characteristic matrix. For example, the elements of G_{cd} and G_{nw} are represented by the respective sensitivity matrices such that the peaks of the sensitivity matrix plots can be traced back to the corresponding network elements.

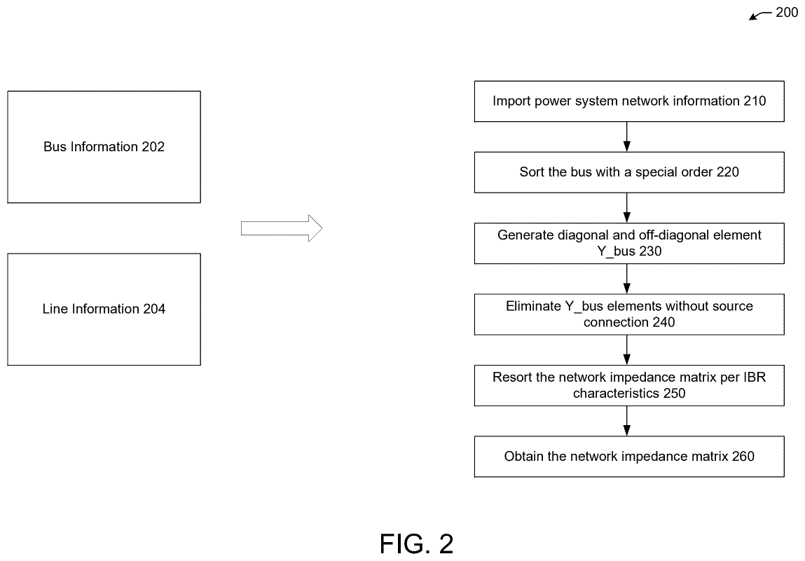

FIG. 2 is an example process 200 for generating the network impedance matrix in accordance with one embodiment of the present disclosure.

Referring to FIG. 2, for the power network 101 of FIG. 1, bus information 202 and line information 204 may be imported at step 210 as power system network information. At step 220, the bus may be sorted with a special order. At step 230, a diagonal and off-diagonal element Y_bus may be generated. At step 240, a Kron reduction may be performed to eliminate the elements in Y_bus without a source connection. At step 250, the network impedance matrix may be resorted per characteristics of the IBRs. At step 260, the network impedance matrix G_{nw} may be obtained based on the impedance characteristics of the IBRs.

In one or more embodiments, the bus information 202 may include, for each bus in the power network 101, whether the bus connects to a power source or intrusion detection system, the voltage rating, the load, the like. The line information 204 may show the buses on each end of a line, the line length, and line characteristics. The sorting and resorting allow for the network impedance matrix to organize the information by rows corresponding to buses so that when the peaks are identified in the plots of T_{cd} and T_{nw}, the corresponding buses for the peaks may be identified as root causes of instabilities indicated by the peaks.

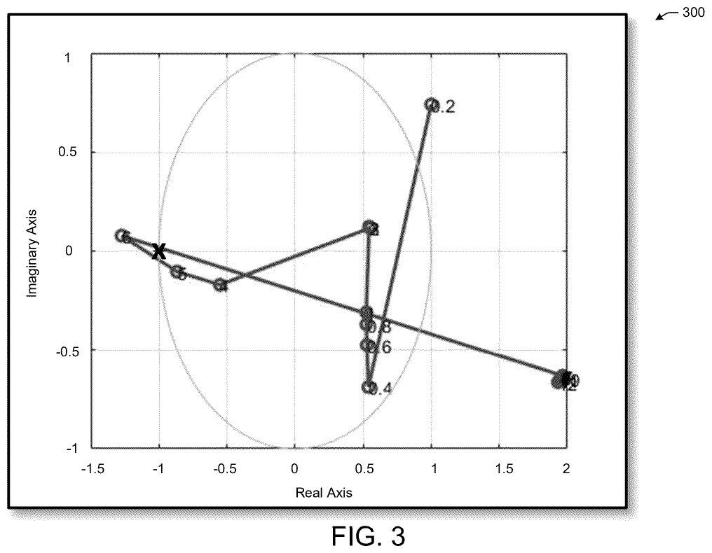

FIG. 3 is a Nyquist plot 300 of an eigenvalue of the characteristic matrix in accordance with one embodiment of the present disclosure.

Referring to FIG. 3, the Nyquist plot 300 shows the real axis as the horizontal axis and the imaginary axis as the vertical axis. The critical point (−1+j0) is encircled in the Nyquist plot 300, indicating that the eigenvalue in the plot is unstable.

To identify the root cause of the instability, the sensitivity matrixes T_{cd} and T_{nw} may be determined as shown above, and plotted as shown in FIG. 1 and in FIGS. 4 and 5 to identify peaks corresponding to root cause locations of the instability. In this manner, the n^{th} eigenvalue of the characteristic matrix is sensitive to elements of G_{cd} and G_{nw}, and those elements may be identified based on the peaks of sensitivity matrix plots. For example, when the eigenvalue of the Nyquist plot 300 indicates an instability, to detect the root cause of the instability, the peaks of eigenvalue on the network and/or IBR sensitivity matrix may correspond to the network element or IBR.

FIG. 4 is a plot 400 of the sensitivity matrix of the n^{th} eigenvalue of a characteristic matrix on IBR impedance in accordance with one embodiment of the present disclosure.

Referring to FIG. 4, the sensitivity matrix T_{cd} of the n^{th} eigenvalue on the characteristic matrix L on G_{cd} is shown according to:

$${T}_{c d} = \frac{\partial L}{\partial {G}_{c {d}_{ij}}} = {u}_{n}^{T} \frac{\partial {G}_{c d}}{\partial {G}_{c {d}_{ij}}} {G}_{n w} {w}_{n} + {u}_{n}^{T} {G}_{c d} \frac{\partial {G}_{n w}}{\partial {G}_{c {d}_{ij}}} {w}_{n} .$$

For given values of the characteristic matrix L on G_{cd} (e.g., the X- and Y-axes), the Z-axes values represent the sensitivity on a given bus.

In the plot 400, peaks of T_{cd} are shown, with the highest peak being at (13, 13, 4.3). The peak at (13, 13, 4.3) may correspond to Bus 9 in the power network 101 of FIG. 1, for example, indicating that Bus 9 is part of the root cause of the instability indicated by the peak. The peak at (13, 13, 4.3) indicates that the n^{th} eigenvalue of the characteristic matrix is sensitive to Bus 9.

FIG. 5 is a plot 500 of the sensitivity matrix of the n^{th} eigenvalue of a characteristic matrix on network impedance in accordance with one embodiment of the present disclosure.

Referring to FIG. 5, the sensitivity matrix T_{nw} of the n^{th} eigenvalue on the characteristic matrix L on G_{nw} is shown according to:

$${T}_{n w} = \frac{\partial L}{\partial {G}_{n {w}_{ij}}} = {u}_{n}^{T} \frac{\partial {G}_{c d}}{\partial {G}_{n {w}_{ij}}} {G}_{n w} {w}_{n} + {u}_{n}^{T} {G}_{c d} \frac{\partial {G}_{n w}}{\partial {G}_{{nw}_{ij}}} {w}_{n} .$$

For given values of the characteristic matrix L on G_{nw} (e.g., the X- and Y-axes), the Z-axes values represent the sensitivity on a given bus.

In the plot 500, peaks of T_{nw} are shown, with the highest peak being at (11, 11, 0.8). The peak at (11, 11, 0.8) may correspond to Bus 4 in the power network 101 of FIG. 1, for example, indicating that Bus 4 is part of the root cause of the instability indicated by the peak. The peak at (11, 11, 0.8) indicates that the n^{th} eigenvalue of the characteristic matrix is sensitive to Bus 4.

Referring to FIGS. 4 and 5, the sensitivity analysis suggests that resonances may be the interaction between Bus 9 and Bus 4, resulting in the identification of the sensitivity region 150 of FIG. 1. As a result, reducing leakage inductance between Bus 4 and Bus 9 may stabilize the system.

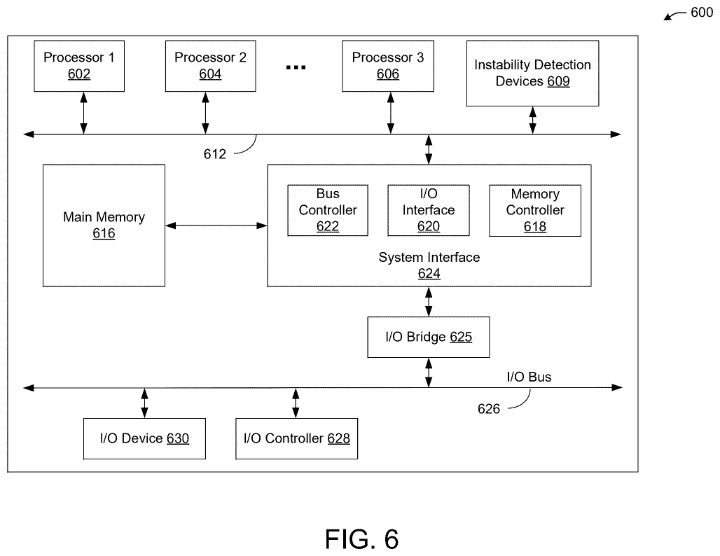

FIG. 6 is a diagram illustrating an example of a computing system 600 that may be used in implementing embodiments of the present disclosure.

For example, the computing system 600 of FIG. 6 may represent computer components capable of facilitating the operations and analyses of FIGS. 1-5. The computer system (system) includes one or more processors 602-606 and one or more instability detection devices 609 (e.g., one or more computer modules capable of performing any operations described with respect to FIGS. 1-5). Processors 602-606 may include one or more internal levels of cache (not shown) and a bus controller 622 or bus interface unit to direct interaction with the processor bus 612. Processor bus 612, also known as the host bus or the front side bus, may be used to couple the processors 602-606 with the system interface 624. System interface 624 may be connected to the processor bus 612 to interface other components of the system 600 with the processor bus 612. For example, system interface 724 may include a memory controller 618 for interfacing a main memory 616 with the processor bus 612. The main memory 616 typically includes one or more memory cards and a control circuit (not shown). System interface 624 may also include an input/output (I/O) interface 620 to interface one or more I/O bridges 625 or I/O devices with the processor bus 612. One or more I/O controllers and/or I/O devices may be connected with the I/O bus 626, such as I/O controller 628 and I/O device 630, as illustrated.

I/O device 630 may also include an input device (not shown), such as an alphanumeric input device, including alphanumeric and other keys for communicating information and/or command selections to the processors 602-606. Another type of user input device includes cursor control, such as a mouse, a trackball, or cursor direction keys for communicating direction information and command selections to the processors 602-606 and for controlling cursor movement on the display device.

System 600 may include a dynamic storage device, referred to as main memory 616, or a random access memory (RAM) or other computer-readable devices coupled to the processor bus 612 for storing information and instructions to be executed by the processors 602-606. Main memory 616 also may be used for storing temporary variables or other intermediate information during execution of instructions by the processors 602-606. System 600 may include a read only memory (ROM) and/or other static storage device coupled to the processor bus 612 for storing static information and instructions for the processors 602-606. The system outlined in FIG. 6 is but one possible example of a computer system that may employ or be configured in accordance with aspects of the present disclosure.

According to one embodiment, the above techniques may be performed by computer system 600 in response to processor 604 executing one or more sequences of one or more instructions contained in main memory 616. These instructions may be read into main memory 616 from another machine-readable medium, such as a storage device. Execution of the sequences of instructions contained in main memory 616 may cause processors 602-606 to perform the process steps described herein. In alternative embodiments, circuitry may be used in place of or in combination with the software instructions. Thus, embodiments of the present disclosure may include both hardware and software components.

A machine readable medium includes any mechanism for storing or transmitting information in a form (e.g., software, processing application) readable by a machine (e.g., a computer). Such media may take the form of, but is not limited to, non-volatile media and volatile media and may include removable data storage media, non-removable data storage media, and/or external storage devices made available via a wired or wireless network architecture with such computer program products, including one or more database management products, web server products, application server products, and/or other additional software components. Examples of removable data storage media include Compact Disc Read-Only Memory (CD-ROM), Digital Versatile Disc Read-Only Memory (DVD-ROM), magneto-optical disks, flash drives, and the like. Examples of non-removable data storage media include internal magnetic hard disks, SSDs, and the like. The one or more memory devices 706 may include volatile memory (e.g., dynamic random access memory (DRAM), static random access memory (SRAM), etc.) and/or non-volatile memory (e.g., read-only memory (ROM), flash memory, etc.).

Computer program products containing mechanisms to effectuate the systems and methods in accordance with the presently described technology may reside in main memory 716, which may be referred to as machine-readable media. It will be appreciated that machine-readable media may include any tangible non-transitory medium that is capable of storing or encoding instructions to perform any one or more of the operations of the present disclosure for execution by a machine or that is capable of storing or encoding data structures and/or modules utilized by or associated with such instructions. Machine-readable media may include a single medium or multiple media (e.g., a centralized or distributed database, and/or associated caches and servers) that store the one or more executable instructions or data structures.

Embodiments of the present disclosure include various steps, which are described in this specification. The steps may be performed by hardware components or may be embodied in machine-executable instructions, which may be used to cause a general-purpose or special-purpose processor programmed with the instructions to perform the steps. Alternatively, the steps may be performed by a combination of hardware, software and/or firmware.

Various modifications and additions can be made to the exemplary embodiments discussed without departing from the scope of the present invention. For example, while the embodiments described above refer to particular features, the scope of this invention also includes embodiments having different combinations of features and embodiments that do not include all of the described features. Accordingly, the scope of the present invention is intended to embrace all such alternatives, modifications, and variations together with all equivalents thereof.

It is understood that the above descriptions are for purposes of illustration and are not meant to be limiting.

As used herein, unless otherwise specified, the use of the ordinal adjectives “first,” “second,” “third,” etc., to describe a common object, merely indicates that different instances of like objects are being referred to and are not intended to imply that the objects so described must be in a given sequence, either temporally, spatially, in ranking, or in any other manner.

Although specific embodiments of the disclosure have been described, one of ordinary skill in the art will recognize that numerous other modifications and alternative embodiments are within the scope of the disclosure. For example, any of the functionality and/or processing capabilities described with respect to a particular device or component may be performed by any other device or component. Further, while various illustrative implementations and architectures have been described in accordance with embodiments of the disclosure, one of ordinary skill in the art will appreciate that numerous other modifications to the illustrative implementations and architectures described herein are also within the scope of this disclosure.

Although embodiments have been described in language specific to structural features and/or methodological acts, it is to be understood that the disclosure is not necessarily limited to the specific features or acts described. Rather, the specific features and acts are disclosed as illustrative forms of implementing the embodiments. Conditional language, such as, among others, “can,” “could,” “might,” or “may,” unless specifically stated otherwise, or otherwise understood within the context as used, is generally intended to convey that certain embodiments could include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

What is claimed is:

1. A method for detecting power network instability and root cause, the method comprising:
identifying, by at least one processor, a network impedance matrix of a power network;
determining, by the at least one processor, impedance matrices for inverter-based resources (IBRs) of the power network;
generating, by the at least one processor, a characteristic impedance matrix based on a product of the network impedance matrix and an IBR impedance matrix of the impedance matrices;
determining, by the at least one processor, a first sensitivity matrix of an n^{th} eigenvalue of the characteristic impedance matrix on the network impedance matrix;
determining, by the at least one processor, a second sensitivity matrix of the n^{th} eigenvalue of the characteristic impedance matrix on the IBR impedance matrix;
identifying, by the at least one processor, a first peak of the first sensitivity matrix;
identifying, by the at least one processor, a second peak of the second sensitivity matrix;
determining, by the at least one processor, based on the first peak, that a first bus of the power network is a root cause of an instability in the power network; and
determining, by the at least one processor, based on the second peak, that the first bus or a second bus of the power network is associated with the root cause of the instability in the power network.

2. The method of claim 1, further comprising:
generating a Nyquist plot of the n^{th} eigenvalue of the characteristic impedance matrix;
determining that a critical point of the Nyquist plot is encircled; and
identifying the instability in the power network based on the critical point of the Nyquist plot being encircled.

3. The method of claim 1, wherein the first sensitivity matrix is a derivative of the characteristic impedance matrix with respect to respective elements of the power network.

4. The method of claim 1, wherein the second sensitivity matrix is a derivative of the characteristic impedance matrix with respect to respective elements of the IBRs of the power network.

5. The method of claim 1, wherein identifying the first peak comprises identifying a highest peak of the first sensitivity matrix, and wherein identifying the second peak comprises identifying a highest peak of the second sensitivity matrix.

6. The method of claim 1, wherein determining that the first bus is the root cause of the instability in the power network is based on values of the first peak corresponding to the first bus in the network impedance matrix, and wherein determining that the first bus or the second bus is associated with the root cause is based on values of the second peak corresponding to the first bus or the second bus in the IBR impedance matrix.

7. The method of claim 1, further comprising generating the network impedance matrix by:
importing network information of the power network;
sorting a bus of the power network;
determining a diagonal and off-diagonal element based on the network information;
removing elements of the diagonal and off-diagonal element that lack a source connection; and
resorting the network impedance matrix per characteristics of the IBRs.

8. A system for detecting power network instability and root cause, the system comprising:
a power network; and
memory coupled to at least one processor configured to:
identify a network impedance matrix of the power network;
determine impedance matrices for inverter-based resources (IBRs) of the power network;
generate a characteristic impedance matrix based on a product of the network impedance matrix and an IBR impedance matrix of the impedance matrices;
determine a first sensitivity matrix of an n^{th} eigenvalue of the characteristic impedance matrix on the network impedance matrix;
determine a second sensitivity matrix of the n^{th} eigenvalue of the characteristic impedance matrix on the IBR impedance matrix;
identify a first peak of the first sensitivity matrix;
identify a second peak of the second sensitivity matrix;
determine, based on the first peak, that a first bus of the power network is a root cause of an instability in the power network; and
determine, based on the second peak, that the first bus or a second bus of the power network is associated with the root cause of the instability in the power network.

9. The system of claim 8, wherein the at least one processor is further configured to:
generate a Nyquist plot of the n^{th} eigenvalue of the characteristic impedance matrix;
determine that a critical point of the Nyquist plot is encircled; and
identify the instability in the power network based on the critical point of the Nyquist plot being encircled.

10. The system of claim 8, wherein the first sensitivity matrix is a derivative of the characteristic impedance matrix with respect to respective elements of the power network.

11. The system of claim 8, wherein the second sensitivity matrix is a derivative of the characteristic impedance matrix with respect to respective elements of the IBRs of the power network.

12. The system of claim 8, wherein to identify the first peak comprises to identify a highest peak of the first sensitivity matrix, and wherein to identify the second peak comprises to identify a highest peak of the second sensitivity matrix.

13. The system of claim 8, wherein to determine that the first bus is the root cause of the instability in the power network is based on values of the first peak corresponding to the first bus in the network impedance matrix, and wherein to determine that the first bus or the second bus is associated with the root cause is based on values of the second peak corresponding to the first bus or the second bus in the IBR impedance matrix.

14. The system of claim 8, wherein the at least one processor is further configured to generate the network impedance matrix by:
importing network information of the power network;
sorting a bus of the power network;
determining a diagonal and off-diagonal element based on the network information;
removing elements of the diagonal and off-diagonal element that lack a source connection; and
resorting the network impedance matrix per characteristics of the IBRs.

15. A non-transitory computer-readable medium storing instructions for detecting power network instability and root cause that, when executed by one or more processors, causes the one more processors to:
identify a network impedance matrix of the power network;
determine impedance matrices for inverter-based resources (IBRs) of the power network;
generate a characteristic impedance matrix based on a product of the network impedance matrix and an IBR impedance matrix of the impedance matrices;
determine a first sensitivity matrix of an n^{th} eigenvalue of the characteristic impedance matrix on the network impedance matrix;
determine a second sensitivity matrix of the n^{th} eigenvalue of the characteristic impedance matrix on the IBR impedance matrix;
identify a first peak of the first sensitivity matrix;
identify a second peak of the second sensitivity matrix;
determine, based on the first peak, that a first bus of the power network is a root cause of an instability in the power network; and
determine, based on the second peak, that the first bus or a second bus of the power network is associated with the root cause of the instability in the power network.

16. The non-transitory computer-readable medium of claim 15, wherein execution of the instructions further causes the one or more processors to:
generate a Nyquist plot of the n^{th} eigenvalue of the characteristic impedance matrix;
determine that a critical point of the Nyquist plot is encircled; and
identify the instability in the power network based on the critical point of the Nyquist plot being encircled.

17. The non-transitory computer-readable medium of claim 15, wherein the first sensitivity matrix is a derivative of the characteristic impedance matrix with respect to respective elements of the power network.

18. The non-transitory computer-readable medium of claim 15, wherein the second sensitivity matrix is a derivative of the characteristic impedance matrix with respect to respective elements of the IBRs of the power network.

19. The non-transitory computer-readable medium of claim 15, wherein to identify the first peak comprises to identify a highest peak of the first sensitivity matrix, and wherein to identify the second peak comprises to identify a highest peak of the second sensitivity matrix.

20. The non-transitory computer-readable medium of claim 15, wherein to determine that the first bus is the root cause of the instability in the power network is based on values of the first peak corresponding to the first bus in the network impedance matrix, and wherein to determine that the first bus or the second bus is associated with the root cause is based on values of the second peak corresponding to the first bus or the second bus in the IBR impedance matrix.
